(19) United States
(12) Patent Application Publication
(10) Pub. No.: US 2002/0096762 A1
(43) Pub. Date: Jul. 25, 2002

(54) Structure of stacked integrated circuits and method for manufacturing the same

(76) Inventors: Wen Chuan Chen, Hsinchu Hsien (TW); Kuo Feng Peng, Hsinchu Hsien (TW); C. H. Chou, Hsinchu Hsien (TW); Allis Chen, Hsinchu Hsien (TW); Nai Hua Yeh, Hsinchu Hsien (TW); Yen Cheng Huang, Hsinchu Hsien (TW); Fu Yung Huang, Hsinchu Hsien (TW); Chief Lin, Hsinchu Hsien (TW); C. S. Cheng, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 09/770,082

(22) Filed: Jan. 24, 2001

(51) Int. Cl. H01L 23/488; H01L 21/44; H01L 21/48

(52) U.S. Cl. 257/723; 438/107; 438/109; 438/612

(57) ABSTRACT

A structure of stacked integrated circuits for mounting on a circuit board includes a substrate, a lower integrated circuit, a plurality of wirings, a plurality of metallic balls, and an upper integrated circuit. The substrate has a first surface formed with signal input terminals and a second surface formed with signal output terminals for electrically connecting to the circuit board. The lower integrated circuit has a first surface adhered to the first surface of the substrate and a second surface formed with a plurality of bonding pads. Each of the wirings has a first end and a second end away from the first end. The first ends are electrically connected to the bonding pads of the lower integrated circuit. The second ends are electrically connected to the signal input terminals on the first surface of the substrate. The plurality of metallic balls are formed on the second surface of the lower integrated circuit. The upper integrated circuit is stacked on the plurality of metallic balls to form a stack with the lower integrated circuit so as to prevent the plurality of wirings from being pressed and damaged by the upper integrated circuit. According to the structure, the stacking processes can be facilitated and the manufacturing costs can be lowered.

### BACKGROUND OF THE INVENTION

1. Field of the Invention

The invention relates to a structure of stacked integrated circuits and method for manufacturing the same, in particular, to a structure of stacked integrated circuits in which integrated circuits can be effectively stacked so as to facilitate the manufacturing processes.

2. Description of the Related Art

In the current technological field, every product needs to be light, thin, and small. Therefore, it is preferable that the integrated circuit has a small volume in order to meet the demands of the products. In the prior art, even if the volumes of integrated circuits are small, they only can be electrically connected to the circuit board in parallel. Because the area of the circuit board is limited, it is not possible to increase the number of the integrated circuits mounted on the circuit board. Therefore, it is difficult to make the products small, thin, and light.

To meet the demands of manufacturing small, thin, and light products, a lot of integrated circuits can be stacked. However, when stacking a lot of integrated circuits, the upper integrated circuit will contact and press the wirings of the lower integrated circuit. In this case, the signal transmission to or from the lower integrated circuit is easily influenced.

Referring to FIG. 1, a structure of stacked integrated circuits includes a substrate 10, a lower integrated circuit 12, an upper integrated circuit 14, a plurality of wirings 16, and an isolation layer 18. The lower integrated circuit 12 is located on the substrate 10. The isolation layer 18 is located on the lower integrated circuit 12. The upper integrated circuit 14 is stacked on the isolation layer 18. That is, the upper integrated circuit 14 is stacked above the lower integrated circuit 12 with the isolation layer 18 interposed between the integrated circuits 12 and 14. Thus, a proper gap 20 is formed between the lower integrated circuit 12 and the upper integrated circuit 14. According to this structure, the plurality of wirings 16 can be electrically connected to the edge of the lower integrated circuit 12. Furthermore, the plurality of wirings 16 connecting the substrate 10 to the lower integrated circuit 12 are free from being pressed when stacking the upper integrated circuit 14 above the lower integrated circuit 12.

However, the above-mentioned structure has the disadvantages to be described hereinbelow. During the manufacturing processes, the isolation layer 18 has to be manufactured in advance, and then, it is adhered to the lower integrated circuit 12. Thereafter, the upper integrated circuit 14 has to be adhered on the isolation layer 18. As a result, the manufacturing processes are complicated, and the manufacturing costs are high.

To solve the above-mentioned problems, it is necessary for the invention to provide a structure of stacked integrated circuits in order to improve the stacking processes of the integrated circuits, facilitate the manufacturing processes, and lower down the manufacturing costs.

### SUMMARY OF THE INVENTION

It is therefore an object of the invention to provide a structure of stacked integrated circuits and method for manufacturing the same in order to effectively stack the integrated circuits and increase the manufacturing speed.

It is therefore another object of the invention to provide a structure of stacked integrated circuits and method for manufacturing the same in order to facilitate the manufacturing processes. The reason is that the currently used apparatus for packing the BGA can be utilized for bonding the metallic balls onto the integrated circuit as an isolation layer.

According to one aspect of the invention, a structure of stacked integrated circuits for mounting on a circuit board includes a substrate, a lower integrated circuit, a plurality of wirings, a plurality of metallic balls, and an upper integrated circuit.

The substrate has a first surface formed with signal input terminals and a second surface formed with signal output terminals for electrically connecting to the circuit board. The lower integrated circuit has a first surface adhered to the first surface of the substrate and a second surface formed with a plurality of bonding pads. Each of the wirings has a first end and a second end away from the first end. The first ends are electrically connected to the bonding pads of the lower integrated circuit. The second ends are electrically connected to the signal input terminals on the first surface of the substrate. The plurality of metallic balls are formed on the second surface of the lower integrated circuit. The upper integrated circuit is stacked on the plurality of metallic balls to form a stack with the lower integrated circuit so as to prevent the plurality of wirings from being pressed and damaged by the upper integrated circuit.

According to this structure, the lower integrated circuit is free from being pressed and damaged by the upper integrated circuit when stacking a plurality of integrated circuits. Thus, the stacking processes can be facilitated and the manufacturing costs can also be lowered.

### BRIEF DESCRIPTION OF THE DRAWINGS

FIG. 1 is a cross-sectional view showing a conventional structure of stacked integrated circuits.

FIG. 2 is a cross-sectional view showing a structure of stacked integrated circuits in accordance with one embodiment of the invention.

FIG. 3 is a pictorial view showing the combination of the substrate and the lower integrated circuit in accordance with the invention.

FIG. 4 is a schematic illustration showing another structure of stacked integrated circuits in accordance with another embodiment of the invention.

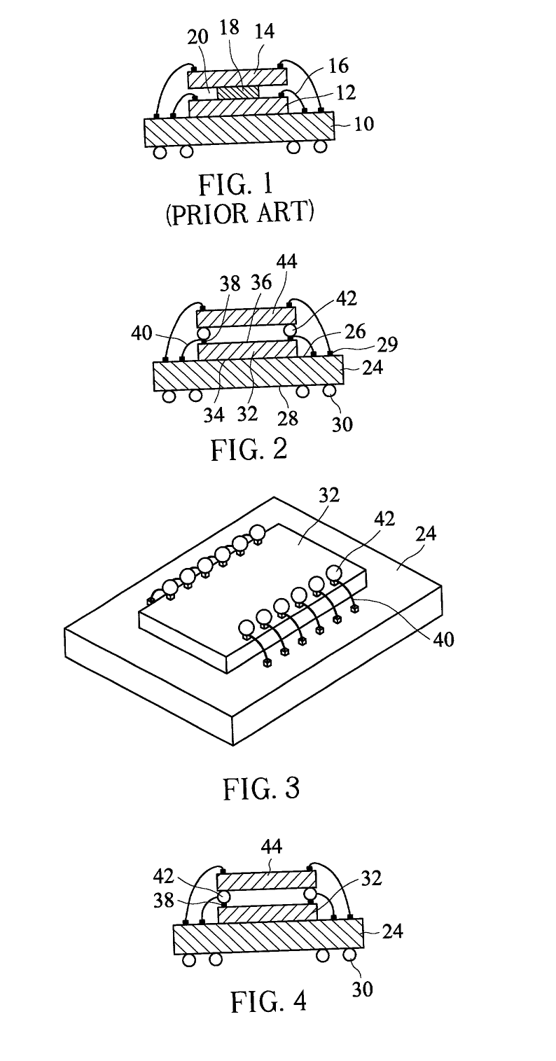

### DETAIL DESCRIPTION OF THE INVENTION

Referring to FIGS. 2 and 3, the structure of stacked integrated circuits of the invention includes a substrate 24, a lower integrated circuit 32, a plurality of wirings 40, a plurality of metallic balls 42, and an upper integrated circuit 44.

The substrate 24 has a first surface 26 and a second surface 28. The first surface 26 is formed with signal input terminals 29 for transmitting the signals from the integrated circuit to the substrate 24. The second surface 28 is formed with signal output terminals 30 for transmitting the signals to the circuit board (not shown). The signal output terminals 30 can be connected to a plurality of metallic balls arranged in the form of a ball grid array (BGA).

The lower integrated circuit 32 has a first surface 34 and a second surface 36. The first surface 34 is adhered onto the first surface 26 of the substrate 24. The second surface 36 is formed with a plurality of bonding pads 38 for electrically connecting to the substrate 24.

One end of each of the plurality of wirings 40 is electrically connected to a bonding pad 38 of the lower integrated circuit 32, while the other end of the wiring 40 is electrically connected to one signal input terminal 29 of the substrate 24. Thus, the signals from the lower integrated circuit 32 can be transmitted to the substrate 24. The wirings 40 can be bonded to the bonding pads 38 of the lower integrated circuit 32 by way of wedge bonding or ball bonding.

A plurality of metallic balls 42 is bonded on the periphery of the second surface 36 of the lower integrated circuit 32 and is coated with an adhesive layer (not shown) for adhering to the upper integrated circuit 44. In this embodiment, the metallic balls 42 are bonded on the ends of the plurality of wirings 40.

Referring to FIG. 4, in the manufacturing processes, the metallic balls 42 can be bonded onto the bonding pads 38 of the lower integrated circuit 32 in advance. Then, the wirings 40 can be bonded to the metallic balls 42 to complete the electrically connection between the lower integrated circuit 32 and the substrate 24.

The upper integrated circuit 44 is arranged on the metallic balls 42 so that the upper integrated circuit 44 can be stacked above the lower integrated circuit 32. At this time, the upper integrated circuit 44 and the lower integrated circuit 32 are separated from each other by the metallic balls 42 so that the plurality of wirings 40 are not pressed by the upper integrated circuit 44.

The above-mentioned structure of stacked integrated circuits of the invention has the advantages described in the following.

1. The metallic balls can be formed on the lower integrated circuit 32 using a typical apparatus for performing the BGA package. Thus, it is not necessary to prepare another apparatus for forming the isolation layer.

2. It is more convenient for the manufacturing processes by using the metallic balls for isolation layer.

3. The manufacturing costs can be lowered because no other apparatus for bonding the conventional isolation layer 18 should be provided.

While the invention has been described by way of example and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A structure of stacked integrated circuits for mounting on a circuit board, comprising:
a substrate having a first surface formed with signal input terminals and a second surface formed with signal output terminals for electrically connecting to the circuit board;
a lower integrated circuit having a first surface adhered to the first surface of the substrate and a second surface formed with a plurality of bonding pads;
a plurality of wirings each having a first end and a second end away from the first end, the first ends being electrically connected to the bonding pads of the lower integrated circuit, the second ends being electrically connected to the signal input terminals on the first surface of the substrate, respectively;
a plurality of metallic balls formed on the second surface of the lower integrated circuit; and
an upper integrated circuit stacked on the plurality of metallic balls to form a stack with the lower integrated circuit so as to prevent the plurality of wirings from being pressed and damaged by the upper integrated circuit.

2. The structure of stacked integrated circuits according to claim 1, wherein the signal output terminals of the substrate are metallic balls arranged in the form of a ball grid array (BGA).

3. The structure of stacked integrated circuits according to claim 1, wherein a plurality of wirings are electrically connected to the periphery of the second surface of the lower integrated circuit.

4. The structure of stacked integrated circuits according to claim 3, wherein the plurality of wirings are electrically connected to the lower integrated circuit by way of wedge bonding.

5. The structure of stacked integrated circuits according to claim 1, wherein the plurality of metallic balls are bonded on the periphery of the second surface of the lower integrated circuit.

6. The structure of stacked integrated circuits according to claim 1, wherein the plurality of metallic balls are bonded onto the plurality of wirings.

7. The structure of stacked integrated circuits according to claim 1, wherein an adhesive layer is coated on the plurality of metallic balls for adhering to the upper integrated circuit.

8. The structure of stacked integrated circuits according to claim 1, wherein the plurality of wirings are bonded to the bonding pads of the lower integrated circuit by way of ball bonding.

9. The structure of stacked integrated circuits according to claim 1, wherein the upper integrated circuit is electrically connected to the first surface of the substrate.

10. The structure of stacked integrated circuits according to claim 9, wherein the upper integrated circuit is electrically connected onto the first surface of the substrate by way of wire bonding.

11. A method for forming a structure of stacked integrated circuits, comprising the steps of:
providing a substrate;
providing a lower integrated circuit having a first surface adhered onto the substrate and a second surface formed with bonding pads;
a plurality of wirings electrically connecting the bonding pads of the lower integrated circuit onto the substrate via a plurality of wirings;
bonding a plurality of metallic balls onto the second surface of the lower integrated circuit; and
stacking an upper integrated circuit on the plurality of metallic balls to form a stack with the lower integrated circuit.

12. The method for manufacturing the structure of stacked integrated circuits according to claim 11, wherein a plurality of wirings are electrically connected to the periphery of the second surface of the lower integrated circuit.

13. The method for manufacturing the structure of stacked integrated circuits according to claim 11, wherein the plurality of wirings are electrically connected to the lower integrated circuit by way of wedge bonding.

14. The method for manufacturing the structure of stacked integrated circuits according to claim 11, wherein the substrate is a substrate in the form of a ball grid array (BGA).

15. The method for manufacturing the structure of stacked integrated circuits according to claim 11, further comprising the steps of:
bonding the plurality of metallic balls onto the second surface of the lower integrated circuit;
electrically connecting the plurality of wirings to the bonding pads of the lower integrated circuit and to the substrate.

16. The method for manufacturing the structure of stacked integrated circuits according to claim 11, wherein the upper integrated circuit is electrically connected to the substrate.

17. The method for manufacturing the structure of stacked integrated circuits according to claim 16, wherein the upper integrated circuit is electrically connected onto the first surface of the substrate by way of wire bonding.
